(19) United States
(12) Patent Application Publication
(10) Pub. No.: US 2023/0367282 A1
(43) Pub. Date: Nov. 16, 2023

(54) AUTOMATICALLY EVOLVING A PROCESS MODEL

(71) Applicant: Universitat Politecnica De Catalunya, Barcelona (ES)

(72) Inventors: Jose Carmona Vargas, Sant Feliu de Llobregat (ES); Lluís Padró Cirera, Vilassar de Mar (ES); Marc Solé Simó, Sant Just Desvern (ES); Josep Sanchez Ferreres, Barcelona (ES)

(73) Assignee: Universitat Politecnica De Catalunya, Barcelona (ES)

(21) Appl. No.: 18/041,005

(22) PCT Filed: Jun. 2, 2021
(86) PCT No.: PCT/EP2021/064772

§ 371 Date: Feb. 8, 2023

(30) Foreign Application Priority Data
Aug. 13, 2020 (EP) 20382750.6

(51) Int. Cl. G05B 19/042

(52) U.S. Cl. CPC G05B 19/0426; G05B 2219/23456

(57) ABSTRACT

Methods are provided of automatically evolving a process model including process-elements and relationships between process-elements. The method comprises receiving user input defining one or more new constraints to be satisfied by the evolved process model. The method further comprises performing an optimization method to find a best solution of a cost function depending on a set of optimization conditions, over a solution space of possible consistent and/or sound process models derivable from the process model to be evolved depending on the one or more new constraints. The set of optimization conditions comprises maximization of constraints satisfaction corresponding to satisfaction of the one or more new constraints and of previous constrains from previous executions of the method. The method still further comprises updating the process model with the obtained best solution. Computer programs and systems are also provided that are suitable for performing such methods.

### TECHNICAL FIELD

The present disclosure relates to methods of automatically evolving a process model including process-elements (e.g. activities, gateways, etc.) and relationships between process-elements. The present disclosure further relates to systems, computing systems and computer programs suitable for performing such evolving methods.

### BACKGROUND

Technical environments may be built around processes, such as e.g. processes for operating machines, technical work-flows, etc. There exist tools for modelling such processes based on formal descriptions through e.g. a visual language that describes processes by means of several visual elements like boxes and arrows in the spirit of other well-known languages like flowcharts. Some of these tools may include functionalities aimed at automatically validating different aspects of the process that is being modelled, such as e.g. consistency of the process, satisfaction of certain restrictions, etc. However, said assisting functionalities are not powerful enough in many usual situations.

An object of the disclosure is to provide new methods, systems and computer programs aimed at providing improved functionalities assisting process modelling.

### SUMMARY OF THE INVENTION

For reasons of completeness and proper understanding, fundamental definitions in the context of present disclosure are provided below.

The concept of constraint may be defined herein as a logical rule or criteria indicated by user to be satisfied by the model in evolution. For example, constraint defined as “C after A” restrict the evolving model to satisfy that activity C is to be executed after activity A.

The concept of relationship may be defined in the context of present disclosure as a relationship between process-elements that causes satisfaction of user-defined constraints by the model in evolution. For example, a relationship between A and C according to which activity C is executed after activity A is a relationship that causes satisfaction of the above constraint defined as “C after A”.

A directly inferred relationship from a constraint may be defined as a relationship explicitly defined by the constraint. For example, a relationship between A and C according to which activity C is executed after activity A is a relationship directly inferred from the above constraint defined as “C after A”.

An indirectly inferred relationship from a constraint may be defined as a relationship which is not explicitly defined by the constraint but preserves soundness of the model in evolution along with directly inferred relationship(s). For example, a relationship between C and an activity other than A that preserves execution of activity C after activity A is a relationship indirectly inferred from the above constraint “C after A”.

A relationship with default value/rule is a relationship neither directly nor indirectly inferred from constraints defined so far and, therefore, a predefined default value/rule is attributed to it. For example, if model to be evolved has activities A, B, C and D all in parallel, and the user defines constraint “A before B”, a directly inferred relationship and several relationships with default value may result from said constraint. Relationship may be directly inferred from the constraint according to which activity A is executed before activity B. And following relationships with default value may be accordingly defined: parallel execution of A and C, parallel execution of B and C, parallel execution of A and D, and parallel execution of B and D.

After that, if user defines constraint “B before C”, a directly inferred relationship, an indirectly inferred relationship, and several relationships with default value may result from said constraint. Relationship may be directly inferred from the constraint according to which activity B is executed before activity C. Relationship may be indirectly inferred from the constraint according to which activity A is executed before activity C, based on transitivity on previous directly inferred relationship “A executed before B” and current directly inferred relationship “B executed before C”. And following relationships with default value may be accordingly defined: parallel execution of A and D, and parallel execution of B and D.

Solution space may be defined as all possible sound models derivable from the process model to be evolved depending on user-defined constraints, including different combinations of directly inferred relationships, indirectly inferred relationships and relationships with default value preserving soundness of the model.

In an aspect, a method (or “evolving” method) is provided for automatically evolving a process model including process-elements and relationships between process-elements. The method comprises receiving user input defining one or more new constraints to be satisfied by the evolved process model. The method further comprises performing an optimization method to find a best solution of a cost function depending on a set of optimization conditions, over a solution space of possible consistent and/or sound process models derivable from the process model to be evolved depending on the one or more new constraints. The set of optimization conditions comprises maximization of constraints satisfaction corresponding to satisfaction of the one or more new constraints and of previous constrains from previous executions of the method (i.e. already existing constraints in the model to be evolved). The method still further comprises updating the process model with the obtained best solution. In some examples, the process model may be a Single-Entry Single-Exit (SESE) model. Soundness of a model may be defined as correctness criteria that guarantees absence of behavioural anomalies, such as e.g. deadlocks or livelocks.

User input may define new constraints to be satisfied by the process model in terms of corresponding process-elements (e.g. activities, gateways, etc.), relationships between said process-elements, and any other process logics and/or relations available in known process modelling. New constraints may refer at least in part to flow control restrictions and/or any other process modelling aspect influencing the functioning of the process that is being modelled.

The proposed method automatically provides an optimal or best evolved model according to optimization criteria, by inspecting all the solution space of sound process models derivable from the model to be evolved depending on the new constraint(s) defined by user input. Optimality of the model to be selected as the best model thus depends on optimization criteria defined through the set of optimization conditions. The condition of maximizing new and previous constraints satisfaction implies that optimization process will find that or those evolved models that satisfy greatest number of new constraints (derived from user input) and previous constraints (already existing in the model to be evolved). If several evolved models are determined as best solution, said models may be provided to user for selection.

An optimization method may be defined as a process aimed at selecting best element or elements, with respect to some criteria, from a set of available or possible elements. Mathematical models implementable by computational techniques may be used to resolve optimization problems. An optimization problem may correspond to maximize or minimize a real function by systematically choosing possible values and computing such values of the function. The generalization of optimization theory and techniques to other formulations encompasses a large area of applied mathematics. In general, optimization includes discovering “best values” of some target function given a defined domain, including a variety of different types of target functions and different types of domains.

According to implementations, performing the optimization method may include performing a (mathematical) problem of constraint satisfaction over the solution space of possible consistent and/or sound process models derivable from the process model to be evolved depending on the one or more new constraints.

In some configurations, performing the optimization method may include performing a multi-objective search method over the solution space of possible consistent and/or sound process models derivable from the process model to be evolved depending on the one or more new constraints. In particular, performing the multi-objective search method may include performing an A* algorithm over the solution space of possible consistent and/or sound process models derivable from the process model to be evolved depending on the one or more new constraints.

In examples of the method, the set of optimization conditions may further comprise prioritizing the maximization of constraints satisfaction with respect to any other optimization condition in the set of optimization conditions.

New constraint(s) may be satisfied by different possible sound process models in the solution space with different new relationships between process-elements, derivable from the process model to be evolved depending on the new constraint(s). That is, different possible sound process models in the solution space with ones or others new relationships may satisfy new constraint(s). Some of said new relationships may be expressed in user input and some other relationships may not be expressed in user input, but all of them cause possible process models that are sound and/or consistent. Basic concepts in the context of present disclosure have been previously described in detail.

The optimization process identifies the best possible sound process model within solution space according to cost function depending on set of optimization conditions, and outputs said best possible sound process model as the evolved model. If no such best possible sound process model is found by the optimization process, because e.g. the user expressed contradictory constraints, the user may be warned that adding expressed new constraint(s) would cause a contradiction and, therefore, the new constraint(s) may be not added and the model may be kept without such new constraint(s).

The set of optimization conditions may further comprise minimization of new indirectly inferred relationships between process-elements indirectly inferable from the process model to be evolved depending on the new constraint(s).

In implementations of the method, the set of optimization conditions may further comprise prioritizing the minimization of new indirectly inferred relationships between process-elements with respect to any other optimization condition in the set of optimization conditions except the maximization of constraints satisfaction.

The set of optimization conditions may further comprise maximizing preservation of previously indirectly inferred relationships between process-elements in the process model from previous executions of the method. Previously indirectly inferred relationships are those already existing in the model to be evolved because they have been derived in previous executions of the proposed method.

According to examples, the set of optimization conditions may further comprise prioritizing the maximization of preserved previously indirectly inferred relationships between process-elements with respect to any other optimization condition in the set of optimization conditions except the maximization of constraints satisfaction and the minimization of new indirectly inferred relationships between process-elements.

In implementations of the method, the set of optimization conditions may further comprise maximizing new and previous relationships between process-elements with default relationship value or rule. The new relationships with default relationship value/rule may correspond to new relationships between process-elements derivable from the process model to be evolved depending on the new constraint(s), to which default relationship value/rule is attributable. And the previous relationships with default relationship value/rule may correspond to previous relationships between process-elements derived in previous executions of the method, to which default relationship value/rule has been attributed.

The set of optimization conditions may further comprise deprioritizing the maximization of new and previous relationships with default relationship value/rule with respect to any other optimization condition in the set of optimization conditions.

In a further aspect, a system (or “evolving” system) is provided for automatically evolving a process model including process-elements and relationships between process-elements. The system comprises a receiving module, an optimization module and an updating module. The receiving module is configured to receive user input defining one or more new constraints to be satisfied by the evolved process model. The optimization module is configured to perform an optimization method to find a best solution of a cost function depending on a set of optimization conditions, over a solution space of possible consistent and/or sound process models derivable from the process model to be evolved depending on the one or more new constraints. The set of optimization conditions comprises maximization of constraints satisfaction corresponding to satisfaction of the one or more new constraints and of previous constrains from previous executions of the method. The updating module is configured to update the process model with the obtained best solution. This “evolving” system is suitable for performing “evolving” methods such as the ones described in other parts of the disclosure. Hence, aspects of such “evolving” methods, such as e.g. functional, structural, advantageous aspects, may be similarly attributable to “evolving” systems.

In a still further aspect, a computer program (or “evolving” computer program) is provided comprising program instructions for causing a computing system to perform methods of automatically evolving a process model including process-elements and relationships between process-elements, such as the ones described in other parts of the disclosure. The computer program may be embodied on a storage medium and/or carried on a carrier signal. This “evolving” computer program is suitable for performing “evolving” methods such as the ones described in other parts of the disclosure. Hence, aspects of such “evolving” methods, such as e.g. functional, structural, advantageous aspects, may be similarly attributable to “evolving” computer programs.

In a still further aspect, a computing system (or “evolving” computing system) is provided for automatically evolving a process model including process-elements and relationships between process-elements, the computing system comprising a memory and a processor, embodying instructions stored in the memory and executable by the processor, and the instructions comprising functionality or functionalities to execute methods of automatically evolving a process model including process-elements and relationships between process-elements, such as the ones described in other parts of the disclosure. This “evolving” computing system is suitable for performing “evolving” methods such as the ones described in other parts of the disclosure. Hence, aspects of such “evolving” methods, such as e.g. functional, structural, advantageous aspects, may be similarly attributable to “evolving” computing systems.

### BRIEF DESCRIPTION OF THE DRAWINGS

Non-limiting examples of the disclosure will be described in the following, with reference to the appended drawings, in which:

FIG. 1 is a block diagram schematically illustrating systems for automatically evolving a process model according to examples.

FIG. 2 is a flow chart schematically illustrating methods of automatically evolving a process model according to examples.

FIGS. 3a-3d schematically illustrate a process model to be evolved and possible consistent and/or sound process models derivable from said evolvable process model depending on new constraints, according to examples.

### DETAILED DESCRIPTION OF THE INVENTION AND OF PARTICULAR EMBODIMENTS

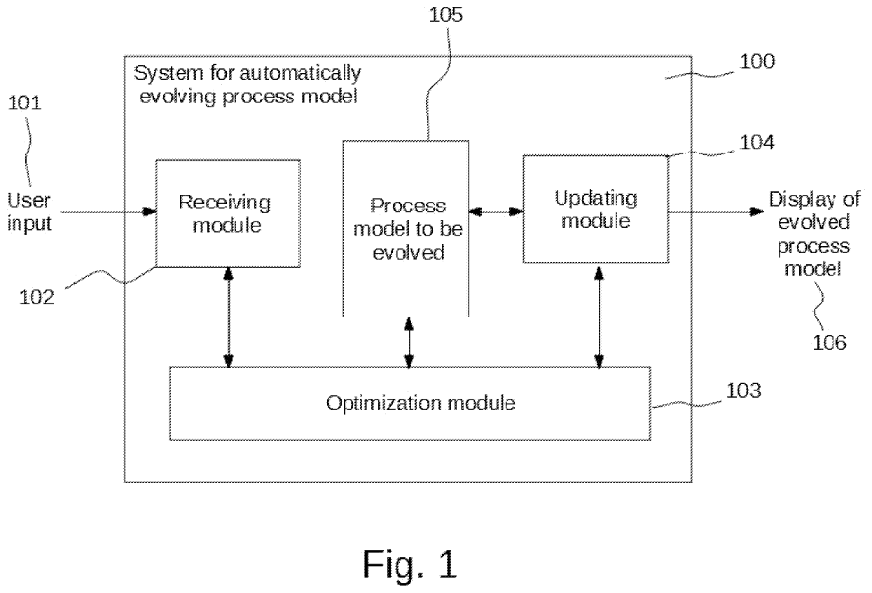

FIG. 1 is a block diagram schematically illustrating systems for automatically evolving a process model according to examples. The evolvable process model 105 may include process-elements and relationships between process-elements, as it will be described in detail with respect to other figures. The evolvable process model 105 may have been retrieved from e.g. a repository of evolvable process models 105 and/or may have been outputted by previous execution of corresponding “evolving” method. Once retrieved or received or obtained, the evolvable process model 105 may have been stored in execution memory until corresponding evolving method according to present disclosure is performed as many times as required until the evolvable process model 105 has been evolved completely or as desired. The evolvable process model 105 may be e.g. a Single-Entry Single-Exit (SESE) model. The evolvable process model 105 may describe control-flow aspects and other process model aspects known in the prior art, such as e.g. the ones defined by standard BPMN 2.0 or any other available standard.

Such systems 100 may comprise a receiving module 102, an optimization module 103 and an updating module 104. The receiving module 102 may be configured to receive user input 101 defining one or more new constraints to be satisfied by the evolvable process model 105 once evolved. The optimization module 103 may be configured to perform an optimization method to find a best solution of a cost (or optimization) function depending on a set of optimization conditions, over a solution space of possible consistent and/or sound process models derivable from the evolvable process model 105 depending on the new constraint(s) as defined by user input 101. The set of optimization conditions may comprise maximization of constraints satisfaction or, in other words, minimization of constraints violation or dissatisfaction. The condition of maximizing constraints satisfaction may correspond to satisfaction of new constraint(s) defined by user input and of previous constrain(s) from previous executions of the method. The updating module 104 may be configured to update the process model 105 with the obtained best solution.

Functionality of performing the optimization method (executable by optimization module 103) may comprise performing a problem of constraint satisfaction over the solution space of possible consistent and/or sound process models derivable from the evolvable process model 105 depending on the new constraint(s).

Functionality of performing the optimization method (executable by optimization module 103) may include performing a multi-objective search method over the solution space of possible consistent and/or sound process models derivable from the evolvable process model 105 depending on the new constraint(s). In particular, functionality of performing the multi-objective search (executable by optimization module 103) may include performing an A* algorithm over the solution space of possible consistent and/or sound process models derivable from the evolvable process model 105 depending on the new constraint(s).

Functionality of performing the optimization method (executable by optimization module 103) may take into account that the set of optimization conditions may further comprise prioritizing the maximization of constraints satisfaction with respect to any other optimization condition in the set of optimization conditions. In other words, the optimization method may be performed attributing maximum priority or weight to maximization of constraints satisfaction (or minimization of constraints dissatisfaction) with respect to remaining conditions in the set of optimization conditions.

In some examples, the new constraint(s) may be satisfied by different possible consistent and/or sound process models with different new indirectly inferred relationships between process-elements. That is, different possible sound process models in the solution space with one(s) or other(s) new inferred relationships (i.e. not defined in user input) may satisfy new constraint(s) defined by user input. In this case, functionality of performing the optimization method (executable by optimization module 103) may take into account that the set of optimization conditions further comprises minimization of new indirectly inferred relationships between process-elements derivable from the evolvable process model 105 depending on the new constraint(s). User input may define new constraint(s) that the process model ideally should accommodate, in terms of new indirectly inferred relationship(s) between process-elements. New constraint(s) may be “translated” into new indirectly inferred relationship(s) between process-elements in the process, and this translation may be performed in different ways by deriving different new indirectly inferred relationship(s) between process-elements. The condition of minimizing new indirectly inferred relationships between process-elements thus pursues to identify possible process model(s) in the solution space with smallest number of new indirectly inferred relationships.

Functionality of performing the optimization method (executable by optimization module 103) may take into account that the set of optimization conditions further comprises prioritizing the minimization of new indirectly inferred relationships between process-elements with respect to any other optimization condition in the set of optimization conditions except the maximization of constraints satisfaction. That is, in some examples, first maximum priority or weight may be attributed to maximization of constraints satisfaction and second maximum priority (below first maximum priority) may be attributed to minimization of new indirectly inferred relationships, with respect to remaining conditions in the set of optimization conditions which may have lower priority than first and second maximum priorities.

Functionality of performing the optimization method (executable by optimization module 103) may take into account that the set of optimization conditions further comprises maximizing preservation of previously indirectly inferred relationships between process-elements in the evolvable process model from previous executions of the method. Previously indirectly inferred relationships are those already existing in the model to be evolved because they have been derived in previous executions of the proposed method. Maximizing preservation of previously indirectly inferred relationships may thus refer to keep maximum number of relationships between process-elements indirectly inferred in previous executions of the method (e.g. during whole evolving of the process model).

Functionality of performing the optimization method (executable by optimization module 103) may take into account that the set of optimization conditions further comprises prioritizing the maximization of preserved previously indirectly inferred relationships between process-elements with respect to any other optimization condition in the set of optimization conditions, except the maximization of constraints satisfaction and the minimization of new indirectly inferred relationships between process-elements. That is, in some implementations, first maximum priority or weight may be attributed to maximization of constraints satisfaction, second maximum priority (below first maximum priority) may be attributed to minimization of new indirectly inferred relationships and third maximum priority (below second maximum priority) may be attributed to maximizing preservation of previously indirectly inferred relationships, with respect to remaining conditions in the set of optimization conditions which may have lower priority than first, second and third maximum priorities.

Functionality of performing the optimization method (executable by optimization module 103) may take into account that the set of optimization conditions further comprises maximizing new and previous relationships with default relationship value/rule. New relationships with default relationship value/rule may correspond to new relationships between process-elements derivable from the evolvable process model 105 depending on the new constraint(s), to which default relationship value/rule is attributable. Previous relationships with default relationship value/rule may correspond to previous relationships between process-elements from previous executions of the method, to which default relationship value/rule has been attributed. Default relationship value/rule may be defined as predefined resolution to be implemented in the process model whenever user input does not explicitly define particular resolution. For example, if user input defines addition of particular activity with no further explicit specification, default relationship value/rule may cause addition of the particular activity sequentially after last added activity, or in parallel with respect to last added activity, etc. depending on predefined default relationship values/rules available for that aim. Maximizing new and previous relationships between process-elements with default relationship value/rule may thus refer to keep maximum number of new and previous relationships between process-elements implemented according to predefined default relationship value/rule.

Functionality of performing the optimization method (executable by optimization module 103) may take into account that the set of optimization conditions further comprises deprioritizing the maximization of new and previous relationships with default relationship value with respect to any other optimization condition in the set of optimization conditions. In other words, maximization of new and previous relationships with default relationship value/rule may be the optimization condition with smallest priority or weight in the set of optimization conditions.

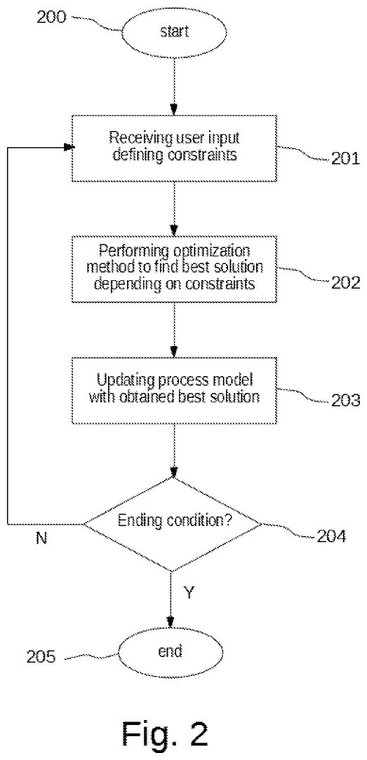

FIG. 2 is a flow chart schematically illustrating methods of automatically evolving a process model according to examples. As generally shown in the figure, such “evolving” methods may be initiated (e.g. at block 200) upon detection of a starting condition such as e.g. a request for starting the method or an invocation of the method from an operator of the system or the like. Since evolving methods according to FIG. 2 are performable by systems according to previous figure, number references from FIG. 1 may be reused in following description of FIG. 2.

Evolving methods may further include (e.g. at block 201) receiving user input 101 defining one or more new constraints to be satisfied by the evolved process model. This functionality implementable at e.g. block 201 may be performed by e.g. receiving module such as module 102 previously described with reference to FIG. 1. Functional details and considerations explained about said module 102 may thus be similarly attributed to method block 201. Evolving methods may further include (e.g. at block 202) performing an optimization method to find a best solution of a cost function depending on a set of optimization conditions, over a solution space of possible consistent and/or sound process models derivable from the process model to be evolved 105 depending on the one or more new constraints. The set of optimization conditions may comprise maximization of constraints satisfaction corresponding to satisfaction of the one or more new constraints and of previous constrains from previous executions of the method. This optimization functionality implementable at e.g. block 202 may be performed by e.g. optimization module such as module 103 previously described with reference to FIG. 1. Functional details and considerations explained about said module 103 may thus be similarly attributed to method block 202.

Evolving methods may further include (e.g. at block 203) updating the evolvable process model 105 with the obtained best solution. This updating functionality implementable at e.g. block 203 may be performed by e.g. updating module such as module 104 previously described with reference to FIG. 1. Functional details and considerations explained about said module 104 may thus be similarly attributed to method block 203.

Evolving methods may further include (e.g. at decision block 204) verifying whether an ending condition is satisfied, in which case the method may proceed to terminate its execution (e.g. block 205) and, otherwise, the method may loop back to e.g. block 201 for receiving new user input 101 and accordingly perform new iteration. Ending condition may refer to e.g. a state of the process model corresponding to final state, completely evolved state, user indication denoting completion of the model, etc.

Evolving methods may terminate (e.g. at block 205) when an ending condition has been detected (at e.g. decision block 204) such as e.g. request for ending the method or an invocation of the method from an operator of the system or the like.

As used herein, the term “module” may be understood to refer to software, firmware, hardware and/or various combinations thereof. It is noted that the modules are exemplary. The modules may be combined, integrated, separated, and/or duplicated to support various applications. Also, a function described herein as being performed by a particular module may be performed by one or more other modules and/or by one or more other devices instead of or in addition to the function performed by the described particular module.

The modules may be implemented across multiple devices, associated or linked to corresponding methods of automatically evolving a process model proposed herein, and/or to other components that may be local or remote to one another. Additionally, the modules may be moved from one device and added to another device, and/or may be included in both devices, associated to corresponding methods of automatically evolving a process model proposed herein. Any software implementations may be tangibly embodied in one or more storage media, such as e.g. a memory device, a floppy disk, a compact disk (CD), a digital versatile disk (DVD), or other devices that may store computer code.

The methods of automatically evolving a process model according to present disclosure may be implemented by computing means, electronic means or a combination thereof. The computing means may be a set of instructions (e.g. a computer program) and then the methods of automatically evolving a process model may comprise a memory and a processor, embodying said set of instructions stored in the memory and executable by the processor. These instructions may comprise functionality or functionalities to execute corresponding methods of automatically evolving a process model such as e.g. the ones described with reference to other figures.

In case the methods of automatically evolving a process model are implemented only by electronic means, a controller of the system may be, for example, a CPLD (Complex Programmable Logic Device), an FPGA (Field Programmable Gate Array) or an ASIC (Application-Specific Integrated Circuit).

In case the methods of automatically evolving a process model are a combination of electronic and computing means, the computing means may be a set of instructions (e.g. a computer program) and the electronic means may be any electronic circuit capable of implementing corresponding method-steps of the methods of automatically evolving a process model proposed herein, such as the ones described with reference to other figures.

The computer program(s) may be embodied on a storage medium (for example, a CD-ROM, a DVD, a USB drive, a computer memory or a read-only memory) or carried on a carrier signal (for example, on an electrical or optical carrier signal).

The computer program(s) may be in the form of source code, object code, a code intermediate source and object code such as in partially compiled form, or in any other form suitable for use in implementing the methods of automatically evolving a process model according to present disclosure. The carrier may be any entity or device capable of carrying the computer program(s).

For example, the carrier may comprise a storage medium, such as a ROM, for example a CD ROM or a semiconductor ROM, or a magnetic recording medium, for example a hard disk. Further, the carrier may be a transmissible carrier such as an electrical or optical signal, which may be conveyed via electrical or optical cable or by radio or other means.

When the computer program(s) is/are embodied in a signal that may be conveyed directly by a cable or other device or means, the carrier may be constituted by such cable or other device or means. Alternatively, the carrier may be an integrated circuit in which the computer program(s) is/are embedded, the integrated circuit being adapted for performing, or for use in the performance of, the methods of automatically evolving a process model proposed herein.

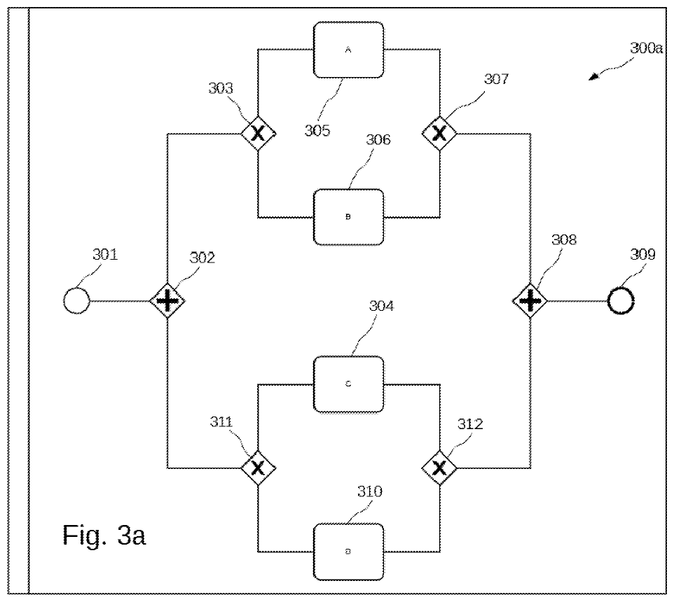

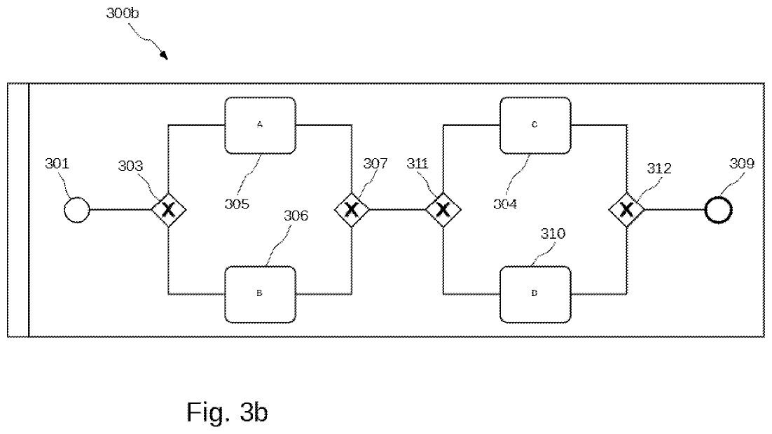

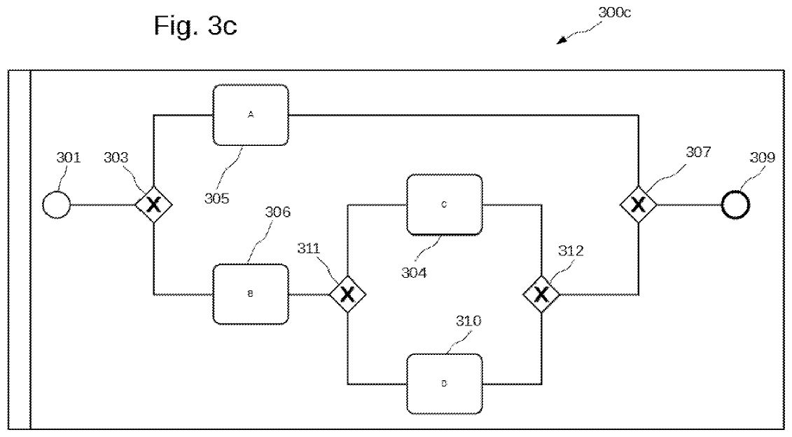

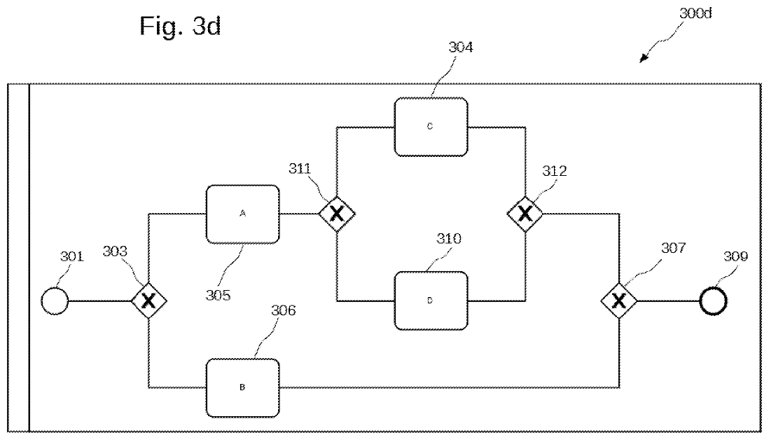

FIGS. 3a-3d schematically illustrate an evolvable process model 300a, and some possible consistent and/or sound process models derivable from said evolvable process model 300a depending on new constraint(s). That is, a partial solution space of possible solutions is shown.

Any model in the solution space may also be an evolvable process model. FIG. 3a shows an example of process model to be evolved 300a and FIGS. 3b-3d illustrate different possible evolutions of the process model 300a within the solution space of possible consistent and/or sound process models derivable from 300a depending on a new constraint (defined by user input). Model to be evolved 300a is shown with a process-element indicating start of the process 301 and another process-element indicating end of the process 309.

In the particular example shown, new constraint may be expressed as “block of C is after A” which means that the activities C 304 and D 310 have to be performed after activity A 306. Evolvable process models may be SESE models and may include process-elements such as e.g. activities 304, 305, 306, 310, “parallel” or AND gateways 302, 308, “conflict” or “choice” gateways 303, 307, 311, 312, and relationships between said process-elements. A selector may identify a subset of activities in the process. The simplest one may be activity selector, which refers to a single activity. By mixing selectors and verbs that represent constraints, relationships between process-elements may be defined. Other basic selectors may be branch selector and block selector. Selectors may recursively work on other selectors, and are well-defined for Single-Entry Single-Exit (SESE) process models.

User input may define constraints to be satisfied by the evolving process model, and may be defined over a language that enables establishing constraints between process-elements or groups of process-elements. To identify arbitrary groups that should be related, this language may incorporate the notion of selectors as defined in other parts of the disclosure.

Selectors may have a basic form like “branch of SELECTOR” and “block of SELECTOR”. In SESE models, any activity is inside a block of activities whose entry point are gateways of the same type, or the start and end events respectively, and no edges can go from the activities inside the block to outside elements and vice versa. The expression SESE-block(S) may denote the activities of the smallest SESE block that includes the activities in S. Gateways 302 and 308 are AND (or “parallel”) gateways, while gateways 303, 307, 311 and 312 are XOR (or “conflict” or “choice”) gateways. Other types of gateway such as the ones available in e.g. BPMN 2.0 or any other known standard may also possible and considerable in the context of present disclosure.

The block selector of a selector SEL, where SEL represents set of activities S is simply the SESE-block(S). For instance, in FIG. 3a, block of B 305 represents {B, A} (i.e. block containing activities 305, 306). In FIG. 3c, block of B 305 represents {B, C, A, D} (i.e. block containing activities 304, 305, 306, 310). A branch selector identifies all the activities that are in a sequential relation with the activities of the given selector S inside the SESE-block(S). For example, in FIG. 3c, branch of B 305 represents the set {B, C, D} (i.e. branch or sequence containing activities 304, 305, 310).

Once user has provided input defining constraint “block of C is after A” referred to model 300a, optimization process may start analysing corresponding solution space, such as the one partially represented by FIGS. 3b-3d. As a way of example, it may be assumed that cost function considers, in order of relevance, minimizing number of violated constraints (or maximizing number of constraints satisfaction) and minimizing number of new indirectly inferred relationships. In the initial state 300a, the cost would be (2, 0), since activity C 304 and activity D 310 are not after activity A 306, and the user input has not explicitly specified that activity C 304 and/or D 310 have to be after the block of activity A 306, which implies that activities C 304 and D 310 have not to be after activity B 305, which is actually happening in the initial situation 300a.

The optimization method may then explore alternative models in the solution space, such as e.g. the ones illustrated by FIGS. 3b-3d. In explored state 300b of FIG. 3b, the cost function evaluates to (0, 2), since activities C 304 and D 310 are after activity A 306, but activities C 304 and D 310 are also after activity B 305. In explored state 300c of FIG. 3c, the cost function evaluates to (2, 2), since activities C 304 and D 310 are after activity B 305, but activities C 304 and D 310 are not after activity A 306. In explored state 300d of FIG. 3d, the cost function evaluates to (0, 0), since activities C 304 and D 310 are after activity A 306 and activities C 304 and D 310 are not after activity B 305. Accordingly, process model 300d of FIG. 3d may be selected as best solution since its function has the lowest pair of values in comparison with the other explored states in solutions space.

Although only a number of examples have been disclosed herein, other alternatives, modifications, uses and/or equivalents thereof are possible. Furthermore, all possible combinations of the described examples are also covered. Thus, the scope of the disclosure should not be limited by particular examples, but it should be determined only by a fair reading of the claims that follow.

What is claimed is:

1. A method of automatically evolving a process model including process-elements and relationships between process-elements, the relationships being defined as a relationship between the process-elements that cause a satisfaction of user-defined constraints by a process model to be evolved, and the user-defined constraints comprising logical rules or criteria indicated by a user, the method comprising:
receiving, by a processor, one or more user-defined constraints to be satisfied by the process model;
performing, by a processor, an optimization method to find a best solution of a cost function depending on a set of optimization conditions, over a solution space of possible consistent and/or sound process models derivable from the process model depending on the received one or more user-defined constraints,
the optimization method comprising: solving a problem of constraint satisfaction over the solution space of possible consistent and/or sound process models, and performing a multi-objective search method over the solution space of possible consistent and/or sound process models; and
the set of optimization conditions comprising: maximizing constraint satisfaction corresponding to a satisfaction of the received one or more user-defined constraints and of previous constraints from previous executions, prioritizing the maximized constraints satisfaction with respect to any other optimization condition in the set of optimization conditions, and minimizing indirectly inferred relationships between process-elements derivable from the process model at least depending on the received one or more user-defined constraints, the indirectly inferred relationships comprising a relationship that is not explicitly defined by a constraint but preserves a soundness of the process model in evolution along with directly inferred relationship(s); and
updating, by a processor, the process model with the obtained best solution.

2. (canceled)

3. (canceled)

4. The method according to claim 1, wherein performing the multi-objective search method includes performing an A* algorithm over the solution space of possible consistent and/or sound process models.

5. (canceled)

6. (canceled)

7. The method according to claim 1, wherein the set of optimization conditions further comprises prioritizing minimizing new indirectly inferred relationships between process-elements with respect to any other optimization condition in the set of optimization conditions except the maximized constraints satisfaction.

8. The method according to claim 7, wherein the set of optimization conditions further comprises maximizing preservation of previously indirectly inferred relationships between process-elements in the process model from previous executions of the method.

9. The method according to claim 8, wherein the set of optimization conditions further comprises prioritizing the maximization of preserved previously indirectly inferred relationships between process-elements with respect to any other optimization condition in the set of optimization conditions except the maximized constraints satisfaction and the minimized new indirectly inferred relationships between process-elements.

10. The method according to claim 1, wherein:
the set of optimization conditions further comprises maximizing new and previous relationships between process-elements with default relationship value;
the new relationships with default relationship value corresponding to new relationships between process-elements derivable from the process model to be evolved depending on the one or more user-defined constraints, to which default relationship value is attributable; and
the previous relationships with default relationship value corresponding to previous relationships between process-elements from previous executions of the method, to which default relationship value has been attributed.

11. The method according to claim 10, wherein the set of optimization conditions further comprises deprioritizing the maximization of new and previous relationships with default relationship value with respect to any other optimization condition in the set of optimization conditions.

12. A computer program product comprising a computer a computer readable storage medium and program instructions stored on the computer readable storage medium for execution by at least one or more processors, the program instructions comprising:
receiving one or more user-defined constraints to be satisfied by a process model to be evolved, the one or more user-defined constraints comprising logical rules or criteria indicated by a user;
performing an optimization method to find a best solution of a cost function depending on a set of optimization conditions, over a solution space of possible consistent and/or sound process models derivable from the process model depending on the received one or more user-defined constraints, the optimization method comprising solving a problem of constraint satisfaction over the solution space of possible consistent and/or sound process models, and performing a multi-objective search method over the solution space of possible consistent and/or sound process models; the set of optimization conditions comprising maximizing constraints satisfaction corresponding to satisfaction of the received one or more user-defined constraints and of previous constraints from previous executions of the method, prioritizing the maximized constraints satisfaction with respect to any other optimization condition in the set of optimization conditions, and minimizing indirectly inferred relationships between process-elements derivable from the process model at least depending on the received one or more user-defined constraints, the indirectly inferred relationships comprising a relationship that is not explicitly defined by a constraint but preserves a soundness of the process model in evolution along with directly inferred relationship(s); and
updating the process model with the obtained best solution.

13. (canceled)

14. (canceled)

15. A system for automatically evolving a process model including process-elements and relationships between process-elements, the relationships being defined as a relationship between the process-elements that cause satisfaction of user-defined constraints by a process model to be evolved, and the user-defined constraints comprising logical rules or criteria indicated by a user, the system comprising:
a receiving module configured to receive one or more user-defined constraints to be satisfied by the process model;
an optimization module configured to perform an optimization method to find a best solution of a cost function depending on a set of optimization conditions, over a solution space of possible consistent and/or sound process models derivable from the process model depending on the received one or more user-defined constraints, the optimization method comprising solving a problem of constraint satisfaction over the solution space of possible consistent and/or sound process models, and performing a multi-objective search method over the solution space of possible consistent and/or sound process models; and the set of optimization conditions comprising maximizing constraints satisfaction corresponding to a satisfaction of the received one or more user-defined constraints and of previous constraints from previous executions of the method, prioritizing the maximized constraints satisfaction with respect to any other optimization condition in the set of optimization conditions, and minimizing indirectly inferred relationships between process-elements derivable from the process model at least depending on the received one or more user-defined constraints, the indirectly inferred relationships comprising a relationship that is not explicitly defined by a constraint but preserves soundness of the process model in evolution along with directly inferred relationship(s); and
an updating module configured to update the process model with the obtained best solution.

16. The method according to claim 9, wherein:
the set of optimization conditions further comprises maximizing new and previous relationships between process-elements with default relationship value;
the new relationships with default relationship value corresponding to new relationships between process-elements derivable from the process model to be evolved depending on the one or more user-defined constraints, to which default relationship value is attributable; and
the previous relationships with default relationship value corresponding to previous relationships between process-elements from previous executions of the method, to which default relationship value has been attributed.
